(19) United States
(12) Patent Application Publication
(10) Pub. No.: US 2011/0298040 A1
(43) Pub. Date: Dec. 8, 2011

(54) SEMICONDUCTOR DEVICE AND METHOD OF MANUFACTURING THE SAME

(75) Inventor: Hun KIM, Seoul (KR)

(73) Assignee: HYNIX SEMICONDUCTOR INC., Icheon-si (KR)

(21) Appl. No.: 12/979,029

(22) Filed: Dec. 27, 2010

(30) Foreign Application Priority Data
Jun. 3, 2010 (KR) 10-2010-0052478

(51) Int. Cl. H01L 29/78; H01L 21/28

(52) U.S. Cl. 257/329; 438/586; 257/E29.262; 257/E21.19

(57) ABSTRACT

A semiconductor device and a method of manufacturing the same are disclosed. By forming a boron nitride film as a sealing film of a buried gate of a cell region from being oxidized, it is possible to improve refresh characteristics, to reduce the number of processes, and to reduce parasitic capacitance so as to improve the characteristics of the device. The semiconductor device includes a recess included in a semiconductor substrate, a gate buried over a bottom of the recess, and a boron nitride film included over the semiconductor substrate including the gate and the recess.

### CROSS-REFERENCE TO RELATED APPLICATION

The present application claims priority to Korean patent application number 10-2010-0052478, filed on 3 Jun. 2010, which is incorporated by reference in its entirety.

### BACKGROUND OF THE INVENTION

1. Field of the Invention

Exemplary embodiments of the present invention relate to a semiconductor device and a method of manufacturing the same, and more particularly to a semiconductor device including a buried gate, and a method for manufacturing the same.

2. Background of the Invention

A semiconductor memory device includes a plurality of unit cells, for example, each including a capacitor and a transistor. The capacitor is used to temporarily store data, and the transistor is used to transfer data between a bit line and the capacitor. The transistor includes three regions, namely, a gate, a source and a drain, and charge transfers between the source and the drain according to a control signal input to the gate. Here, the charge transfers through a channel region.

In the case where the transistor is formed on a semiconductor substrate, a method of forming a gate on the semiconductor substrate and doped impurities into both sides of the gate so as to form a source and a drain may be used. As a data storage capacity of a semiconductor memory device increases, a size of each unit cell decreases. That is, a design rule of the capacitor and the transistor included in the unit cell decreases. Thus, some effects such as a short channel effect and Drain Induced Barrier Lower (DIBL) occur in the transistor, and thus an operational reliability decreases. By maintaining a threshold voltage such that the cell transistor performs a normal operation, side effects generated due to a shortened channel length may be solved. Therefore, according to a known art, a concentration of doped impurities in a channel region may be set high to reduce the side effects.

However, if the concentration of the impurities doped into the channel region increases, an electric field of a Storage Node (SN) junction increases, thereby lowering the refresh characteristics of a semiconductor memory device. In order to reduce the lowering of the refresh characteristics, a cell transistor having a three-dimensional channel structure in which a channel extends in a vertical direction may be used such that the channel length of the cell transistor is maintained even if the design rule decreases. That is, even if a channel width of a horizontal direction is short, since the channel length of the vertical direction is secured, impurity doping concentration may be reduced and thus refresh characteristics may not deteriorate.

In addition, as a degree of integration of a semiconductor device increases, a distance between a gate and a bit line may decrease. In this case, a parasitic capacitance may increase, and thus operation margin of a sense amplifier for amplifying data transferred through the bit line may deteriorate, and also the operational reliability of the semiconductor device may deteriorate.

### BRIEF SUMMARY OF THE INVENTION

Various embodiments of the present invention are directed to providing a semiconductor device and a method for manufacturing the same that substantially obviate one or more problems due to limitations and disadvantages of the related art.

In accordance with an exemplary embodiment of the present invention, a semiconductor device comprising: a recess formed in a semiconductor substrate; a gate buried in the recess; and a boron nitride film included over the gate.

The gate includes any one selected from among tungsten, titanium nitride and a combination thereof. Further comprising a gate oxide film formed over the recess. Further comprising a barrier metal layer formed over the recess. The barrier metal layer includes any one selected from among titanium, titanium nitride and a combination thereof.

Further comprising a bit line contact plug formed in the boron nitride film and coupled to a source/drain region of the semiconductor substrate. The bit line contact plug comprises any one of a polysilicon layer, a metal layer and a combination thereof.

In accordance with an exemplary embodiment of the present invention, a method of manufacturing a semiconductor device, the method comprising: etching a semiconductor substrate to form a recess; forming a conductive material over a bottom of the recess to form a gate; and forming a boron nitride film over the gate.

Further comprising: forming a gate oxide film in the recess; and forming a barrier metal layer over the gate oxide film. The forming of the gate includes: forming a conductive material over the recess of the semiconductor substrate; and etching the conductive material such that the conductive material remains at least on the bottom of the recess. The conductive material comprises any one selected from among tungsten, titanium nitride and a combination thereof. Further comprising: etching the boron nitride film to form a bit line contact hole exposing the semiconductor substrate; and burying a conductive material in the bit line contact hole to form a bit line contact plug. The conductive material comprises tungsten.

It is to be understood that both the foregoing general description and the following detailed description of the present invention are exemplary and explanatory and are intended to provide further explanation of the invention as claimed.

### BRIEF DESCRIPTION OF THE DRAWINGS

FIGS. 1A and 1B are cross-sectional views showing a semiconductor device including a buried gate and a method of manufacturing the same according to an exemplary embodiment of the present invention; and

FIG. 2A to 2E are cross-sectional views showing a semiconductor device and a method of manufacturing the same according to another exemplary embodiment of the present invention.

### DESCRIPTION OF EMBODIMENTS

Reference will now be made in detail to the embodiments of the present invention, examples of which are illustrated in the accompanying drawings. Wherever possible, the same reference numbers will be used throughout the drawings to refer to the same or like parts.

Recently, in order to reduce parasitic capacitance between a gate and a bit line of a semiconductor device, a buried gate structure in which a gate is formed in a recess is being developed. In the buried gate structure, a conductive material is formed in the recess of the semiconductor substrate, and the conductive material is coated with an insulating film such that the gate is buried in the semiconductor substrate, thereby realizing electrical isolation from a bit line or a bit line contact plug formed on the semiconductor substrate in which a source and a drain are formed. A semiconductor device including such a buried gate and a method of manufacturing the same will now be described.

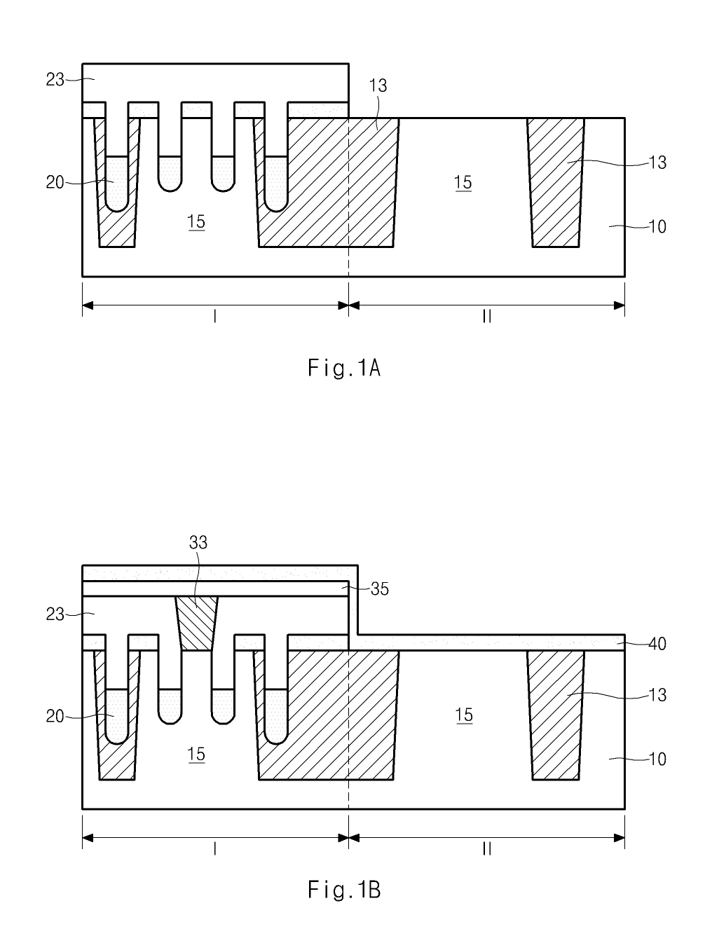

FIGS. 1A and 1B are cross-sectional views showing a semiconductor device according to an exemplary embodiment of the present invention and a method of manufacturing the same. First, referring to FIG. 1A, a semiconductor substrate 10 including a cell region I and a peripheral region II is etched so as to form a device isolation trench defining an active region 15. Thereafter, an oxide film is buried in the device isolation trench so as to form a device isolation film 13. Next, the device isolation film 13 and the active region 15 of the cell region I are etched so as to form recesses. Then, a gate oxide film (not shown) and a barrier metal layer (not shown) are formed on, for example, the entire surface including the recesses. Here, the barrier metal layer (not shown) may be formed of a titanium nitride (TiN) film. Next, a conductive material is formed on the bottoms of the recesses in which the barrier metal layer (not shown) may be formed so as to form buried gates 20. The buried gates 20 may be formed of a material including tungsten.

Next, a sealing layer 23 is deposited, for example, on the entire surface including the recesses in which the buried gates 20 are formed. The sealing film 23 is formed in order to seal the buried gates of the cell region I during an oxidization process for forming a gate oxide film in the peripheral region II. The sealing film 23 may be formed of a Low-Pressure (LP) nitride film or a Spin-On-Dielectric (SOD) oxide film. Here, a liner nitride film may be additionally deposited before the deposition of the SOD oxide film.

In the subsequent process of FIG. 1B, a bit line contact plug 33 is formed in the sealing film 23 of the cell region I, and the sealing film 23 of the peripheral region II is etched so as to expose the semiconductor substrate 10. Thereafter, an oxidization process of forming a gate oxide film in the peripheral region II is performed and a planar gate forming process is performed.

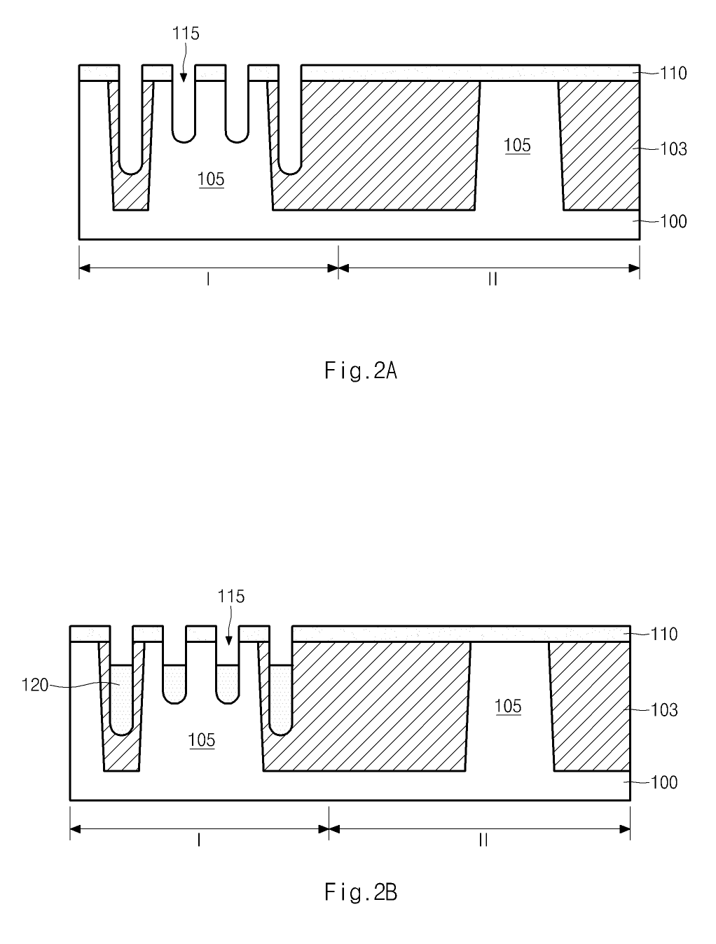

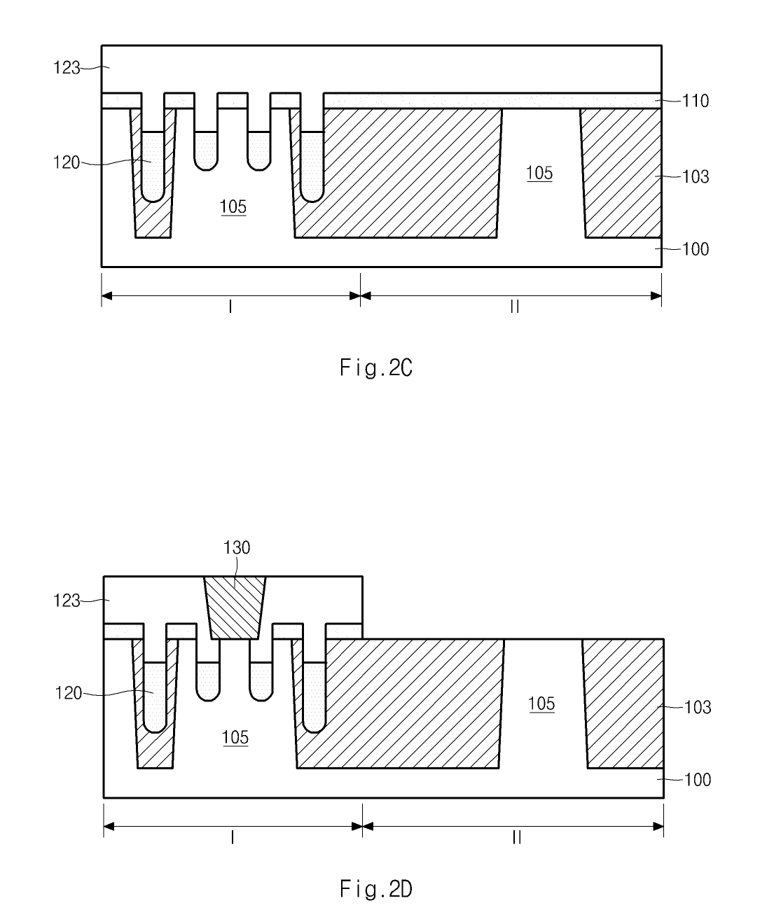

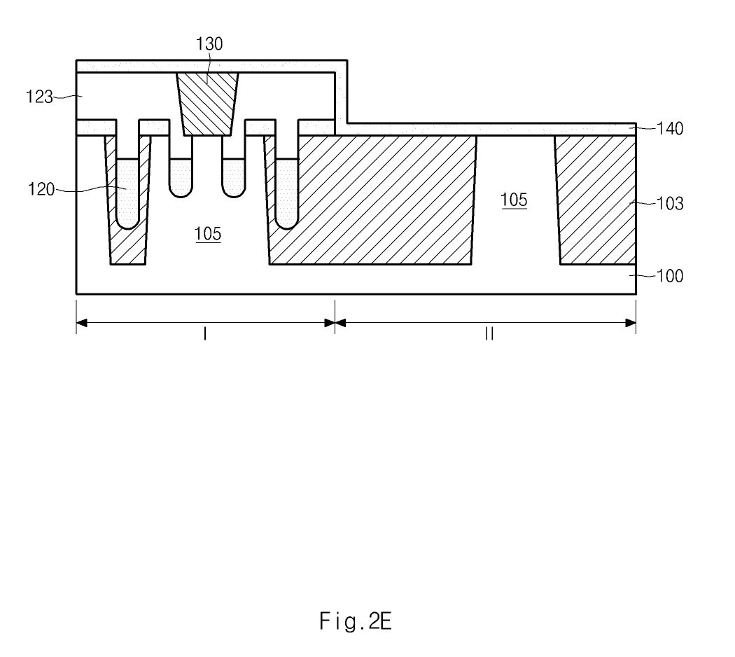

FIG. 2A to 2E are cross-sectional views showing a semiconductor device and a method of manufacturing the same according to another exemplary embodiment of the present invention. First, referring to FIG. 2A, a semiconductor substrate 100 including a cell region I and a peripheral region II is etched so as to form a device isolation trench defining an active region 105. Next, an oxide film may be buried in the device isolation trench and then may be planarized and etched so as to form a device isolation film 103.

Next, according to an example, an oxide film pattern 110 defining a gate region is formed over the semiconductor substrate 100 in which the device isolation film 103 is formed. The device isolation film 103 and the active region 105 are etched using the oxide film pattern 110 as a mask so as to form a recess 115. Here, the depths of the recess 115 in the respective regions may be different by a difference in an etching selection ratio between the device isolation film 103 formed of an oxide film and the active region 105 formed of silicon. That is, the recess 115 formed in the device isolation film 103 may be deeper than the recess 115 formed in the active region 105. In the peripheral region II, a planar gate protruding from the substrate may be formed, and thus the recess 115 may not be formed in the peripheral region II.

Referring to FIG. 2B, a gate oxidization process is performed in the cell region I so as to form a gate oxide film (not shown) on the surface of the recess 115. Subsequently, a barrier metal layer (not shown) may be formed over the entire surface including the recess 115 and the oxide film pattern 110. The barrier metal layer (not shown) may be formed of a titanium nitride (TiN) film and the thickness thereof may be about 50 to 70 Å. Then, a conductive material may be formed over the oxide film pattern 110 including the recess 115.

The conductive material is formed of any one selected from among tungsten, titanium nitride, and a combination thereof. Here, the tungsten may be formed using a Chemical Vapor Deposition (CVD) method with a thickness of about 1400 to 1600 Å.

Next, a Chemical Mechanical Polishing (CMP) process may be performed until the oxide film pattern 110 is exposed, thereby planarizing the conductive material. Thereafter, the conductive material may be further etched by an etch-back process so as to form buried gates 120. Each buried gate 120 may have a shape in which the conductive material is removed up to a certain depth from the upper side of the recess 115 and have a thickness of 600 to 800 Å from the bottom of the recess 115.

Referring to FIG. 2C, a sealing film 123 is deposited over the semiconductor substrate 100 including the recess 115 in which the buried gates 120 are formed. Here, the sealing film 123 may have a thickness of about 600 to 800 Å. The sealing film 123 is formed in order to seal the buried gate 120 formed in the cell region during an oxidization process for forming a gate oxide film in the peripheral region. The sealing film 123 may be formed of a low-k material film, for example, a boron nitride film. The boron nitride film has excellent heat conductivity and insulation properties and low stress properties (−100 to 400 Mpa). In addition, the boron nitride film has excellent light transmission properties and dielectric properties, high strength and low moisture absorption properties. By using the boron nitride film as the sealing film 123, the refresh characteristics may be improved compared with the case of using the LP nitride film. If the existing SOD oxide film is used as the sealing film, the process may become complicated by a deposition process of a liner nitride film. However, if the boron nitride film is used as the sealing film 123, such a process may be omitted and thus the number of processes may be reduced.

Referring to FIG. 2D, a mask pattern (not shown) defining a bit line contact region is formed over the sealing film 123. The mask pattern (not shown) may be formed of any one selected from among carbon, silicon oxynitride (SiON) and a combination thereof. Then, the sealing film 123 may be etched using the mask pattern (not shown) as a barrier so as to form a bit line contact hole, and then the mask pattern (not shown) is removed. The bit line contact hole is formed such that the semiconductor substrate 100 is exposed between the buried gates 120 formed in the active region 105. Next, any one of a polysilicon layer, a metal layer and a combination thereof may be formed over the entire surface including the bit line contact hole, and then an etch-back process is performed so as to form a bit line contact plug 130. Next, a mask pattern (not shown) for opening the peripheral region II is formed over the sealing film 123 and the bit line contact plug 130. Then, the sealing film 123 and the oxide film pattern 110 of the peripheral region II may be etched using the mask pattern (not shown) as a mask.

Referring to FIG. 2E, a gate oxidization process may be performed so as to form a gate oxide film 140 over the sealing film 123 of the cell region I and the surface of the semiconductor substrate 100 of the peripheral region II. The gate oxide film 140 may be a gate of a transistor in the peripheral region II. Thereafter, the process of forming the gate in the peripheral region II and a process of forming a bit line in the peripheral region II may be performed using a known art.

As described above, by forming the boron nitride film as the sealing film for blocking a transfer path of oxygen ions into the cell region I, a titanium nitride film which is a barrier metal layer (not shown) of the buried gates 120 of the cell region I may not be oxidized during the gate oxidization process for forming the gate oxide film 140 in the peripheral region II. Further, it is possible to improve the refresh characteristics of the device, to reduce the number of processes, and to reduce parasitic capacitance.

The semiconductor device and the method of manufacturing the same according to the present invention may have following effects.

First, by using the boron nitride film as the sealing film, refresh characteristics may be improved compared with the case of using the LP nitride film. Second, by using the boron nitride film as the sealing film, the number of processes may decrease compared with the case of using the SOD oxide film. Third, by using a low-k material as the sealing film, parasitic capacitance may decrease.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A semiconductor device comprising:
a recess formed in a semiconductor substrate;
a gate buried in the recess; and
a boron nitride film included over the gate.

2. The semiconductor device according to claim 1, wherein the gate includes any one selected from among tungsten, titanium nitride and a combination thereof.

3. The semiconductor device according to claim 1, further comprising a gate oxide film formed over the recess.

4. The semiconductor device according to claim 1, further comprising a barrier metal layer formed over the recess.

5. The semiconductor device according to claim 4, wherein the barrier metal layer includes any one selected from among titanium, titanium nitride and a combination thereof.

6. The semiconductor device according to claim 1, further comprising a bit line contact plug formed in the boron nitride film and coupled to a source/drain region of the semiconductor substrate.

7. The semiconductor device according to claim 6, wherein the bit line contact plug comprises any one of a polysilicon layer, a metal layer and a combination thereof.

8. A method of manufacturing a semiconductor device, the method comprising:
etching a semiconductor substrate to form a recess;
forming a conductive material over a bottom of the recess to form a gate; and
forming a boron nitride film over the gate.

9. The method according to claim 8, further comprising:
forming a gate oxide film in the recess; and
forming a barrier metal layer over the gate oxide film.

10. The method according to claim 8, wherein the forming of the gate includes:
forming a conductive material over the recess of the semiconductor substrate; and
etching the conductive material such that the conductive material remains at least on the bottom of the recess.

11. The method according to claim 8, wherein the conductive material comprises any one selected from among tungsten, titanium nitride and a combination thereof.

12. The method according to claim 8, further comprising:
etching the boron nitride film to form a bit line contact hole exposing the semiconductor substrate; and
burying a conductive material in the bit line contact hole to form a bit line contact plug.

13. The method according to claim 12, wherein the conductive material comprises tungsten.
